(19) United States
(12) Patent Application Publication
(10) Pub. No.: US 2023/0123680 A1
(43) Pub. Date: Apr. 20, 2023

(54) Correction and compensation method in semiconductor manufacturing process

(71) Applicant: United Semiconductor (Xiamen) Co., Ltd., Xiamen (CN)

(72) Inventors: XIONGWU HE, Xiamen (CN); WEIGUO XU, Xiamen (CN); YUAN-CHI PAI, Xiamen (CN); WEN YI TAN, Xiamen (CN)

(73) Assignee: United Semiconductor (Xiamen) Co., Ltd., Xiamen (CN)

(21) Appl. No.: 17/527,172

(22) Filed: Nov. 16, 2021

(30) Foreign Application Priority Data
Oct. 20, 2021 (CN) 202111219942.5

(51) Int. Cl. H01L 21/67; G05B 19/418; G03F 7/20

(52) U.S. Cl. CPC H01L 21/67276; G05B 19/41875; G03F 7/7025; G03F 7/70633; G05B 2219/45031

(57) ABSTRACT

The invention provides a correction and compensation method in a semiconductor manufacturing process. The method includes the following steps: providing a machine, the machine is at least used for exposure manufacturing of a first product and a second product, performing period maintenance (PM) on the machine, recording an original offset map before and after the period maintenance of the machine is performed, the original offset map has an original exposure size, and adjusting the original exposure size of the original offset map to correspond to a first exposure size of the first product, and performing a first offset compensation correction on the first product. And adjusting the original exposure size of the original offset map to correspond to a second exposure size of the second product, and performing a second offset compensation correction on the second product.

### BACKGROUND OF THE INVENTION

### 1. Field of the Invention

The present invention relates to the field of semiconductor manufacturing process, in particular to a method for quickly finding out the offset value of the semiconductor machine after the period maintenance (PM) is performed.

### 2. Description of the Prior Art

In the field of semiconductor manufacturing, most devices belong to laminated structures. When each layer structure is formed, whether the overlay between the layer structure and the previous layer structure is accurate will have a great influence on the quality of the semiconductor structure.

Many factors can cause the offset between different layers of the semiconductor structure, including the errors of the machine itself, or extra errors may occur between each layer of the structure of the product when the machine is used for manufacturing the product. In order to eliminate these offset errors as much as possible, the monitor wafer is usually used to test the errors of the machine, or the monitor wafer is used to simulate the manufacturing process of semiconductor products, and a number of pilot run are carried out to find out the offset values generated in the manufacturing process and correct them according to these offset values.

However, the above-mentioned pilot run steps need to be repeated many times to find out the offset value, which is a heavy burden on the manufacturing process and will consume many monitor wafers in the process, which is not conducive to cost saving.

### SUMMARY OF THE INVENTION

The invention provides a correction and compensation method in semiconductor manufacturing process, which includes providing a machine, which is at least used in the exposure process of a first product and a second product, performing a periodic maintenance (PM) on the machine, and recording an original offset map of the machine before and after the periodic maintenance, the original offset map has an original exposure size, and adjusting the original exposure size of the original offset map to correspond to a first exposure size of the first product, performing a first offset compensation correction on the first product, and adjusting the original exposure size of the original offset map to correspond to a second exposure size of the second product, and performing a second offset compensation correction on the second product.

The problem to be solved by the present invention is to provide a novel correction and compensation method for semiconductor manufacturing process, so as to reduce the number of pilot runs, thereby improving the productivity and saving the cost. The concept of the invention is that the original offset map is linearly adjusted to generate offset maps of corresponding products, and the offset maps are respectively corrected and compensated for different products. The method of the invention is helpful to reduce the numerical value of the offset error, thereby reducing the number of pilot runs and reducing the cost.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a flow chart of a correction and compensation method in a semiconductor manufacturing process provided by the present invention.

FIG. 2 shows a schematic diagram of converting an offset map generated after the periodic maintenance of a machine to offset maps of different products.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Generally, there are two main reasons for the alignment offset errors caused by external influences in the manufacturing process of semiconductor products. One is the alignment errors generated by the machine itself, and the other is the alignment errors generated in the manufacturing process of products (for example, with advanced process control (APC), for example, different batches and different layer structures of a certain product may generate errors. Under normal circumstances, the errors generated by the machine itself and the errors generated by the product (by the APC system) each have some data stored in the machine or in the database to compensate for the generated alignment offset. However, after the machine runs for a period of time, the machine need to perform a periodic maintenance (PM) to prolong the service life of the machine. After the periodic maintenance is performed, all conditions of the machine will be reset. Under the condition that many parameters change, the previously stored compensation data is no longer suitable for the machine and the APC system after the periodic maintenance is performed. Therefore, it is necessary to re-find the data used to compensate the alignment offset, and a large number of pilot run need to be re-found.

In other words, in the general semiconductor manufacturing process, the offset error between different layers can be divided into two situations, namely the offset error caused by the machine itself and the offset error caused by the product (by the APC system). After the period maintenance is performed to the machine, it is necessary to perform multiple pilot runs to re-find the compensation data suitable for correcting the offset, so it will consume a lot of time and many monitor wafers, which will have a great negative impact on productivity and cost.

The problem to be solved by the present invention is to provide a novel correction and compensation method for semiconductor manufacturing process, so as to reduce the number of pilot runs mentioned above, thereby improving the productivity and saving the cost.

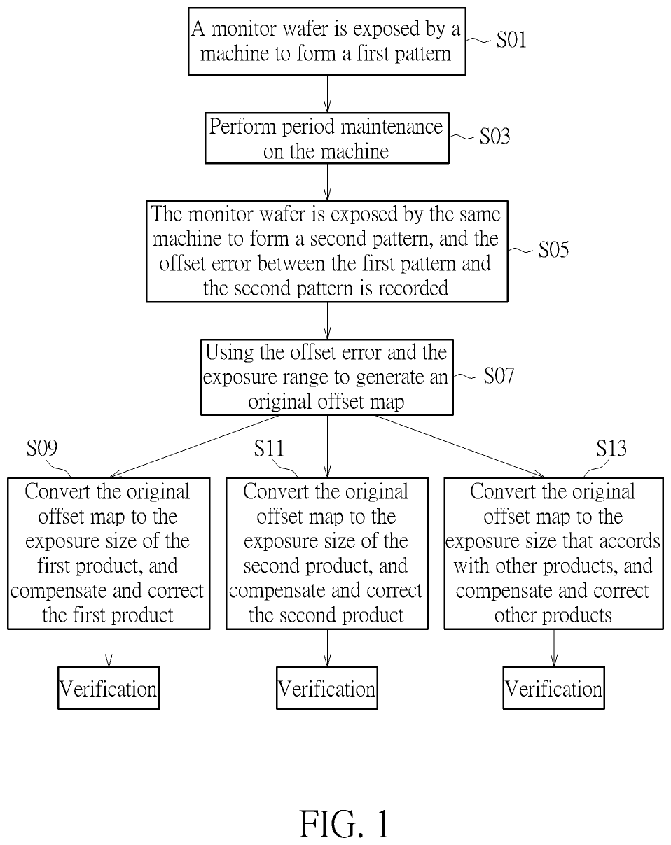

FIG. 1 shows a flow chart of a correction and compensation method in a semiconductor manufacturing process provided by the present invention. As shown in FIG. 1, firstly, as shown in step S01, a machine is provided, and before the period maintenance (PM) is performed to the machine, an monitor wafer (or a test wafer) is used for exposure in the machine, and then a first pattern is formed on the monitor wafer. In this embodiment, the shape of the first pattern is not limited, and it can be any suitable shape. The purpose of forming the first pattern here is to compare the first pattern with the second pattern formed after the periodic maintenance on the machine, and find out the offset error between the two patterns.

In addition, in this step, when the machine is used to form the first pattern on the monitor wafer, it is preferable to use the maximum exposure range allowed by the machine for exposure. Taking this embodiment as an example, the maximum exposure area formed on the monitor wafer is about 26 mm*33 mm, but it is not limited to this. In other words, as far as possible, the monitor wafer is exposed in a larger range. In this way, since the exposure range required in the manufacturing process of most products will be smaller than the maximum exposure range of the machine, the maximum exposure range of the machine can be more accurately converted into the exposure range required by different products, and the offset correction accuracy of subsequent products can be improved. This part will be described in the following paragraphs.

Then, as shown in step S03, a periodic maintenance (PM) is performed on the machine. After the periodic maintenance is performed, many conditions change because the machine is reset. At this time, the correction data originally stored in the machine or database to correct the offset value is no longer suitable for the machine after the periodic maintenance is performed. For example, if a product A is formed before the machine is periodically maintained, and a set of parameters D1 is used to correct and compensate the offset of product A, then the set of parameters D1 is not applicable to another product B formed after the machine is periodically maintained. On the other hand, if one layer structure C-1 of a product C is formed before the machine is periodically maintained, and a set of parameters D2 is used to correct and compensate the offset of this layer C-1 of product C, then this set of parameters D2 is not applicable to the next layer structure C-2 of product C formed after the machine is periodically maintained (the above-mentioned codes A, B, C, C-1, C-2, D1, D2, etc. are examples for convenience and are not shown in the drawing).

As shown in step S05, after the machine is periodically maintained, find out the offset error before and after the machine is periodically maintained. To achieve this goal, the monitor wafer is exposed in the machine, and then a second pattern is formed on the monitor wafer. Here, the second pattern preferably has the same shape as the first pattern mentioned above. In addition, when forming the second pattern, it is set that the machine uses the same parameters as when forming the first pattern, but since the conditions of the machine are changed due to the periodic maintenance, although the first pattern and the second pattern use the same parameters, they are usually formed at different positions on the monitor wafer, and the offset value between them is the offset error generated before and after the periodic maintenance of the machine.

Using the above steps S01 to S05, the user can find out the offset error of the machine itself before and after the periodic maintenance, and find out the appropriate correction and compensation parameters according to the offset error.

In the conventional steps, after the machine is periodically maintained, because many conditions have changed, the machine is regarded as a new machine, all the previously stored compensation data are discarded, and the suitable compensation data are searched again by using multiple pilot run steps, which will consume a lot of time and cost (many monitor wafers).

In the present invention, patterns are formed on the monitor wafer before and after performing the periodic maintenance of the machine, and the offset error between the two patterns is recorded. That is to say, some of the new compensation data generated after periodic maintenance is determined based on the situation of the machine before the periodic maintenance, and not all the compensation data are completely discarded, so that some of pilot runs can be reduced.

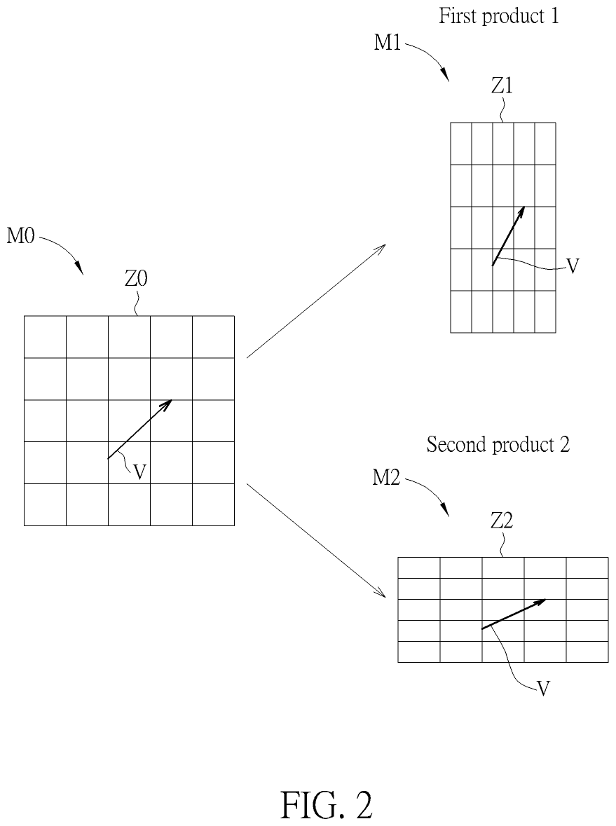

Except for the above steps S01˜S05 to find out the offset errors generated before and after the periodic maintenance of the machine, the present invention continues to carry out subsequent steps, including mapping the offset errors generated before and after the periodic maintenance of the machine to each product. Please refer to steps S07, S09, S11, S13 shown in FIG. 1 and FIG. 2. FIG. 2 shows a schematic diagram of converting an offset map generated after the periodic maintenance of a machine to offset maps of different products. As shown in FIG. 2, in the above steps S01-S05, the offset error generated before and after periodic maintenance of the machine end has been measured, and the numerical value of the offset error is recorded in the exposure range, that is, it becomes an offset map. More specifically, the range Z0 of the offset map (also called the original offset map) M0 on the left side of FIG. 2 is the same as the exposure range in the above-mentioned step S01 or step S05 (for example, the maximum exposure range is 26 mm*33 mm, but it is not limited to this), and the exposure range Z0 mentioned here can also be called the original exposure size Z0 in the following paragraphs, which represents the exposure range in the machine. The offset between the first pattern and the second pattern (that is, the offset of the pattern before and after the periodic maintenance is performed) is recorded in the exposure range in the form of offset vector V. That is, the original offset map M0 is formed by recording the offset vector V in the original exposure size Z0.

The right side of FIG. 2 shows the exposure ranges required by different products. For example, the exposure size required by the first product 1 is Z1 and the exposure size required by the second product 2 is Z2. Preferably, the exposure size Z1 and Z2 are smaller than the original exposure size Z0. In this step, the size of the original exposure size Z0 of the original offset map M0 is adjusted to be equal to the exposure sizes Z1 and Z2 of the first product 1 and the second product 2 respectively by linear adjustment. At the same time, since the original exposure size Z0 of the original offset map M0 is adjusted, the offset vector V therein is also adjusted accordingly. The adjusted exposure size and vector form an offset map M1 corresponding to the first product 1, and form an offset map M2 corresponding to the second product 2 respectively, as the compensation basis for the first product 1 and the second product 2.

The concept of the present invention is that an offset map M1 and an offset map M2 are generated from the original offset map M0 after linear adjustment, and the offset map M1 and the offset map M2 are respectively corrected and compensated for the first product 1 and the second product 2. In other words, it is assumed that the offset errors (recorded in the original offset map M0) generated after performing the periodic maintenance of the machine will be reflected in equal proportions on products with different exposure sizes. In other words, the offset error measured at the machine after performing the periodic maintenance is transferred to the APC system at the products, which is used as the reference value for correction and compensation of the APC system.

It is worth noting that although the above paragraph only describes that the original offset map M0 is linearly adjusted to correspond to the first product 1 and the second product 2 respectively, if the machine is suitable for more products (for example, the machine may be suitable for exposure of the third product, the fourth product or more products), the original offset map M0 can also be linearly converted into other more offset maps by the above method. As shown in step S13 of FIG. 1, it includes the conversion of offset maps for more different products.

In addition, in this embodiment, setting the exposure range of the original offset map M0 of the machine as the maximum exposure range allowed by the machine can make the exposure range of most products smaller than the original exposure size Z0 of the original offset map M0. Therefore, when linearly converting to the exposure size of other products, the reduced exposure size can be obtained by calculating the linear interpolation, which will have better accuracy. On the contrary, if the original exposure size Z0 of the original offset map M0 is not smaller than the exposure size of the product, it may be necessary to estimate the insufficient exposure size by extraploation, and the accuracy may be slightly worse than the above. Therefore, the original exposure size Z0 of the preferred original offset map M0 can be set as the maximum exposure range allowed by the machine, but the present invention is not limited to this.

After the original offset map M0 is mapped to each product to generate the corresponding offset map, correction and compensation are carried out according to the respective offset map of each product. Next, verify the product in the APC system to confirm whether the offset error is within the allowable range. If the verification is passed, the next process can be continued in the APC system. Otherwise, if the verification is not passed, the correction and compensation should be repeated (for example, more pilot runs may be conducted again, etc.).

The step of mapping the original offset map M0 to each product and correcting and compensating the offset map of each product is helpful to reduce the number of subsequent pilot runs. For example, according to the applicant's experimental results, most products that don't have very high requirements for offset error pass the verification directly after the above steps, so the processes and expenses (cost wafers, etc.) for pilot run are saved, and other product processes in the subsequent APC system can be continued. However, a few products with higher requirements for offset error may not be verified at one time, but the method of the invention is also helpful to reduce the value of offset error, thus reducing the steps and cost of pilot run.

Based on the above description and drawings, the present invention provides a correction and compensation method in semiconductor manufacturing process, including providing a machine, which is at least used for the exposure process of a first product 1 and a second product 2, performing a periodic maintenance (PM) on the machine, and recording an original offset map M0 before and after the periodic maintenance of the machine, wherein the original offset map has an original exposure size Z0, and adjusting the original exposure size Z0 of the original offset map. According to a first exposure size Z1 of the first product 1, a first offset compensation correction is performed on the first product 1, and the original exposure size Z0 of the original offset map M0 is adjusted to correspond to a second exposure size Z2 of the second product 2, and a second offset compensation correction is performed on the second product 2.

In some embodiments of the present invention, the original exposure size Z0 is the same as a maximum exposure size allowed by the machine.

In some embodiments of the present invention, the first exposure size Z1 of the first product 1 and the second exposure size Z2 of the second product 2 are equal to or smaller than the original exposure size Z0.

In some embodiments of the present invention, the first exposure size Z1 is different from the second exposure size Z2.

In some embodiments of the present invention, the method of adjusting the original exposure size Z0 to correspond to a first exposure size Z1 of the first product 1 and performing a first offset compensation correction on the first product 1 includes: adjusting the original exposure size Z0 to the same size as the first exposure size Z1 in a linear adjustment manner, and performing a compensation correction step on the first product 1 with an offset value recorded on the adjusted original offset map M0 after the above steps.

In some embodiments of the present invention, after the first offset compensation correction is performed on the first product 1, it further includes more than one pilot run on the first product 1 to confirm whether an exposure offset value of the first product 1 is within an allowable range.

In some embodiments of the present invention, after the first offset compensation correction is performed on the first product 1, the first product 1 further includes a plurality of product offset compensation (that is, compensation correction is continued in the APC system).

In some embodiments of the present invention, the method for recording an original offset map of the machine before and after the periodic maintenance includes: before the periodic maintenance of the machine is performed, exposing a monitor wafer with a mask to form a first pattern on the wafer, after the periodic maintenance of the machine is performed, forming a second pattern on the same monitor wafer with the same mask, and observing and recording the offset error between the first pattern and the second pattern.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A correction and compensation method in a semiconductor manufacturing process, comprising:
providing a machine, which is at least used for the exposure processes of a first product and a second product respectively;
performing a periodic maintenance (PM) on the machine, and recording an original offset map of the machine before and after the periodic maintenance, wherein the original offset map has an original exposure size; and
adjusting the original exposure size of the original offset map to correspond to a first exposure size of the first product, performing a first offset compensation correction on the first product, and adjusting the original exposure size of the original offset map to correspond to a second exposure size of the second product, and performing a second offset compensation correction on the second product.

2. The correction and compensation method in a semiconductor manufacturing process according to claim 1, wherein the original exposure size is the same as a maximum exposure size allowed by the machine.

3. The correction and compensation method in a semiconductor manufacturing process according to claim 1, wherein the first exposure size of the first product and the second exposure size of the second product are equal to or less than the original exposure size.

4. The correction and compensation method in a semiconductor manufacturing process according to claim 1, wherein the first exposure size is different from the second exposure size.

5. The correction and compensation method in a semiconductor manufacturing process according to claim 1, wherein the method of adjusting the original exposure size to correspond to a first exposure size of the first product and performing a first offset compensation correction on the first product comprises:
adjusting the original exposure size to the same size as the first exposure size by a linear adjustment method; and
after the above steps, performing a compensation correction step on the first product with an offset value recorded on the adjusted original offset map.

6. The correction and compensation method in a semiconductor manufacturing process according to claim 1, wherein after the first offset compensation correction is performed on the first product, one or more pilot run is performed on the first product to confirm whether an exposure offset value of the first product is within an allowable range.

7. The correction and compensation method in a semiconductor manufacturing process according to claim 1, wherein after the first offset compensation correction is performed on the first product, further comprising performing a plurality of product offset compensations for the first product.

8. The correction and compensation method in a semiconductor manufacturing process according to claim 1, wherein the method of recording the original offset map of the machine before and after the periodic maintenance comprises:
before the periodic maintenance is performed, a mask is used to expose a monitor wafer to form a first pattern on the wafer;
after the periodic maintenance is performed, a second pattern is formed on the same monitor wafer with the same mask, and an offset between the first pattern and the second pattern is observed and recorded.
